(19) United States
(12) Patent Application Publication
(10) Pub. No.: US 2026/0226654 A1
(43) Pub. Date: Aug. 6, 2026

(54) Deterministic Onsite Synthesis of Perovskite Emitters via Confined Local Heating

(71) Applicant: Massachusetts Institute of Technology, Cambridge, MA (US)

(72) Inventors: Farnaz Niroui, Cambridge, MA (US); Weikun Zhu, Cambridge, MA (US); Shelly Ben-David, Columbus, OH (US); Patricia Helena Jastrzebska-Perfect, Cambridge, MA (US); William Jack, San Francisco, CA (US)

(21) Appl. No.: 19/154,531

(22) PCT Filed: Mar. 8, 2024
(86) PCT No.: PCT/US2024/018994

§ 371 Date: Aug. 7, 2025

Related U.S. Application Data
(60) Provisional application No. 63/489,396, filed on Mar. 9, 2023.

(51) Int. Cl. C30B 29/12; B82Y 10/00; B82Y 20/00; C30B 7/14; G06N 10/40; H10H 20/01; H10H 20/812

(52) U.S. Cl. CPC C30B 29/12; B82Y 20/00; C30B 7/14; G06N 10/40; H10H 20/016; H10H 20/812; B82Y 10/00

(57) ABSTRACT

A method of forming deterministic perovskite nanocrystals on a substrate is disclosed. The method includes preparing a perovskite forming precursor solution comprising a mixture of a solvent, perovskite precursors, and optionally surface passivation ligands and/or a host matrix. This perovskite forming precursor solution is deposited on a substrate by spin-coating, blade-coating or other deposition techniques to produce a layer comprising perovskite precursors, also referred to as a deposited perovskite forming precursor film. Then, a region of the film is locally heated to transform the perovskite precursors into perovskite nanocrystals and deterministically form an arbitrary pattern comprising clusters of the perovskite nanocrystals with control down to a single nanocrystal. The localized heating may be accomplished using thermal scanning probe lithography or lasers or a combination.

This application claims priority to U.S. Provisional Patent Application Ser. No. 63/489,396, filed Mar. 9, 2023, the disclosure of which is incorporated herein by reference in its entirety.

This invention was made with government support under DMR2144136 awarded by the National Science Foundation. The government has certain rights in the invention.

### BACKGROUND

Metal halide perovskites have emerged as a rapidly growing material system offering superior and readily tunable properties along with cost-efficient and scalable processability, enabling applications in electronics, optoelectronics, photovoltaics, and quantum information technologies.

However, leveraging their full potential has been limited by challenges of nanoscale patterning. In particular, extension to applications in quantum technologies necessitates precision in patterning down to the sub-20 nm regime. Perovskite quantum emitters are conventionally formed colloidally through chemical synthesis leading to nanocrystals dispersed stochastically in solution. Integrating these materials into nanoscale devices and those for quantum applications requires precise manipulation of the nanocrystals at the individual nanocrystal level and their on-demand integration with other fabricated optical and electrical elements, which has been a long-standing challenge limiting the field.

Therefore, it would be beneficial if there were a method of synthesizing perovskite emitters in deterministic locations and with controlled properties. Further, it would be advantageous if this method was compatible with current micro and nanofabrication strategies.

### SUMMARY

A method of deterministically forming perovskite nanocrystals on a substrate is disclosed. The method includes preparing a perovskite forming precursor solution comprising a mixture of a solvent, perovskite precursors, and optionally surface passivation ligands and/or a host matrix. This perovskite forming precursor solution is deposited on a substrate by spin-coating, blade-coating or other deposition techniques to produce a layer comprising the perovskite precursors, also referred to as a deposited perovskite forming precursor film. Then, a region of the film is locally heated to transform the perovskite precursors into perovskite nanocrystal(s) and deterministically form a desired pattern comprising the perovskite nanocrystals. The localized heating may be accomplished using thermal scanning probe lithography or lasers or a combination.

According to one embodiment, a method of forming nanocrystals on a substrate is disclosed. The method comprises preparing a perovskite forming precursor solution; depositing the perovskite forming precursor solution on a substrate to produce a layer comprising perovskite precursors, referred to as a deposited perovskite forming precursor film; and locally heating a region of the deposited perovskite forming precursor film to transform the perovskite precursors into perovskite nanocrystals and deterministically form an arbitrary pattern comprising clusters of the perovskite nanocrystals. In some embodiments, the perovskite forming precursor solution comprises a mixture of a solvent and perovskite precursors. Optionally, the perovskite forming precursor solution also comprises surface passivation ligands and/or a host matrix. In certain embodiments, the surface passivation ligands are oleylamine, oleic acid, octylamine bromide or a mixture thereof. In certain embodiments, the host matrix comprises a polymer. In certain embodiments, the host matrix is poly (methyl methacrylate), polystyrene or spin-on glass. In some embodiments, the perovskite forming precursor solution is deposited using spin-coating or blade-coating.

In some embodiments, the local heating is performed using a thermal scanning probe. In some embodiments, the local heating is performed using a laser. In certain embodiments, the laser is used in presence of an optical/plasmonic feature to allow light localization resulting in localized heating. In some embodiments, the method also comprises exposing the perovskite nanocrystals to a post-growth solution comprising surface passivation ligands. In some embodiments, the post-growth solution may also include a solvent. In other embodiments, the post-growth solution also includes a solvent and one or more perovskite precursors. In some embodiments, the method also comprises depositing an inert gas and/or a solid encapsulate to encapsulate the perovskite nanocrystals, wherein the solid encapsulate is impermeable to oxygen and moisture. In certain embodiments, the solid encapsulate comprises poly (methyl methacrylate), parylene, polystyrene or spin-on glass.

In some embodiments, nanocrystals with a single photon emitter are generated. In certain embodiments, growth temperature is varied to allow direct formation of single photon emitting nanocrystals. In certain embodiments, a thickness of the deposited perovskite forming precursor film is varied to allow direct formation of single photon emitting nanocrystals. In certain embodiments, a concentration of perovskite precursors in the perovskite forming precursor solution is varied to allow direct formation of single photon emitting nanocrystals.

According to another embodiment, a perovskite nanocrystal having a single photon emitter produced using the method described above is disclosed.

According to another embodiment, an optoelectronic device comprising the perovskite nanocrystal described above is disclosed. The optoelectronic device is selected from the group consisting of solar cells, light-emitting diodes, lasers, photodetectors, memristors, and quantum light sources.

According to another embodiment, a quantum device comprising the perovskite nanocrystal described above is disclosed. The quantum device is selected from the group consisting of quantum computers and quantum sensors.

### BRIEF DESCRIPTION OF THE DRAWINGS

For a better understanding of the present disclosure, reference is made to the accompanying drawings, in which like elements are referenced with like numerals, and in which:

FIGS. 1A-1D show the synthesis of perovskite nanocrystals through thermal scanning probe lithography;

FIG. 2A shows a photoluminescence (PL) map of a film embedded with locally grown nanocrystals

FIG. 2B shows the PL spectra of different perovskite nanocrystals;

FIG. 3A shows an example PL map of a patterned array of nanocrystals;

FIGS. 3B-3D show a room temperature intensity correlation [g⁽²⁾(τ)], time trace, and photoluminescent spectrum, respectively; FIGS. 3E-3F show the intensity correlation [g⁽²⁾(0)] as a function of precursor concentration and growth temperature, respectively;

FIGS. 3G-3H show the effects of post-treatment on the intensity correlation;

FIG. 4A shows an atomic force microscope (AFM) scan of a circular feature before introducing patterned emitters in the center of the feature;

FIG. 4B shows the atomic force microscope (AFM) scan of a circular feature after introducing patterned emitters in the center of the feature; and

FIGS. 5A-5B show simulations of the electric field intensity distribution and the Purcell enhancement of a patterned emitter within a circular Bragg grating optical cavity, respectively.

### DETAILED DESCRIPTION

The disclosure is directed toward a scanning probe-based technique for the on-substrate synthesis of halide perovskite emitters. This approach leverages a localized heat source that confines perovskite on-site growth down to single emitters. With increased patterning resolution enabled by this technique and compatibility with micro/nanofabrication strategies, on-site integration with existing optoelectronic structures is possible. In addition to spatial and growth control, this technique offers knobs over composition, size, number of emitters, and surface passivation. Utilizing this technique, deterministic halide perovskite single photon sources with spatial control have been demonstrated. Further, these halide perovskite nanocrystals are integrable with photonic structures to further engineer their emission characteristics.

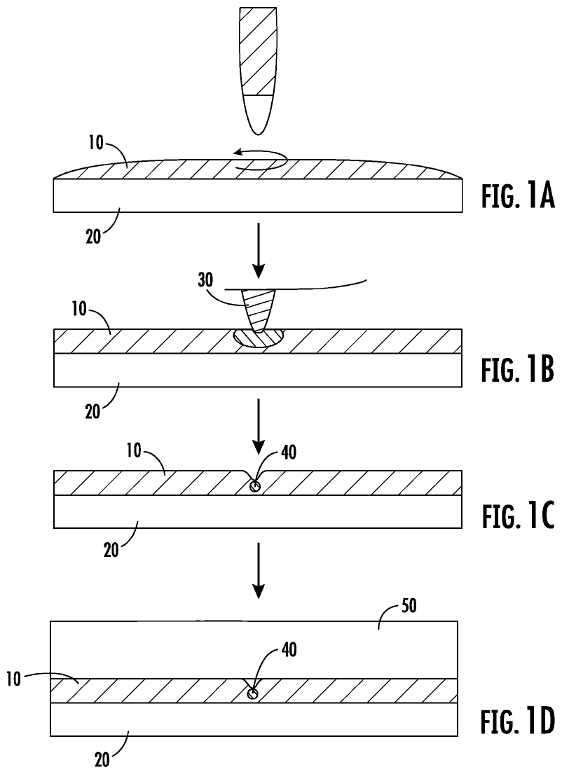

FIGS. 1A-1D show the nanocrystal fabrication process. First, as shown in FIG. 1A, a perovskite forming precursor solution 10 is deposited on a substrate 20. The perovskite forming precursor solution 10 facilitates the formation of perovskite nanocrystals and comprises two or more perovskite precursors, which may be metal halide perovskite precursors, such as cesium iodide, lead iodide, cesium bromide and lead bromide. The perovskite forming precursor solution 10 also comprises a solvent. The solvent may be a single solvent or a mixture of solvents. In some embodiments, the perovskite forming precursor solution 10 also includes surface passivation ligands. In some embodiments, the perovskite forming precursor solution 10 also includes a host matrix. In certain embodiments, both surface passivation ligands and a host matrix are included in the perovskite forming precursor solution 10. Various different surface passivation ligands may be used, such as oleylamine, oleic acid, octylamine bromide or mixtures thereof. The host matrix may be a polymer, such as poly (methyl methacrylate) (PMMA), which is optically passive. Other materials, such as polystyrene, parylene, or spin-on glass may also be used. The substrate 20 may be any suitable substrate, such as a silicon wafer, a silicon oxide wafer, a silicon nitride wafer or other surfaces which are composed of semiconductors, metals or dielectrics and their patterned combinations selected as suited for the desired application. In some embodiments, the substrate 20 may be planar. In other embodiments, the substrate 20 may be nonplanar and may include other pre-fabricated features needed for the eventual nanocrystal integration into functional structures and devices, such as transistors, electrodes, photonic elements and other devices. The perovskite forming precursor solution 10 is then deposited on the surface of the substrate 20. This may be done using spin-coating, blade-coating or another deposition technique. This process results in a layer of perovskite forming precursor solution 10, also referred to as a deposited perovskite forming precursor film. In some embodiments, the thickness of the deposited perovskite forming precursor film may be 5 nm, 10 nm, 20 nm, 30 nm, 50 nm, or greater. In certain embodiments, the thickness of the deposited perovskite forming precursor film may be 20 nm or more. In some embodiments, the deposited perovskite forming precursor film may be up to 10 microns in thickness.

Next, as shown in FIG. 1B, a localized heat source, such as a thermal scanning probe 30 is used to provide the formation energy needed to transform the perovskite forming precursor into perovskite nanocrystals 40. In other words, localized growth is achieved by thermal scanning probe lithography. The size of the tip of the thermal scanning probe 30 may depend on the particular application. In some embodiments, the tip may be as small as a few atoms. Further, the size and shape of the tip represent another parameter that may be used to tune the specific characteristics of the nanocrystals that will be formed. The temperature of the thermal scanning probe 30 may be selected to be greater than the forming temperature of the particular perovskite that is being used. The resulting perovskite nanocrystal 40 is shown in FIG. 1C.

The scanning thermal probe allows for the deterministic formation of an arbitrary pattern composed of clusters of perovskite nanocrystals 40, such as perovskite quantum dots. As described below, the resolution of the pattern may be further refined to single-site growth, where down to single nanocrystals (e.g., individual quantum dots) may be achieved, leading to applications including single-photon sources. The growth process may be conducted in an inert environment for improved stability.

After the growth of perovskite nanocrystals, their crystal size, emission wavelength, numbers per site, and quality may be further controlled through exposure to a post-growth solution. This post-growth solution comprises surface passivation ligands, such as those described above. In some embodiments, this post-growth solution also includes a solvent. Further, in certain embodiments, the post-growth solution may also include a solvent and one or more perovskite precursors. Further, the selection of the perovskite precursors (if any), the particular surface passivation ligands and solvents may differ from those used in the perovskite forming precursor solution, depending on the post-growth modification that is desired. The post-growth solution may selectively dissolve smaller nanocrystals formed during growth and heal defects of the remaining nanocrystals. The solvent for the post-growth solution is selected to dissolve any post-growth precursor and passivation ligands but not the host matrix, and may, in some embodiments, be octadecane. Additionally, as shown in FIG. 1D, the perovskite nanocrystals 40 may be further encapsulated by an inert gas or by deposition of a solid encapsulate 50 using a solution-or vapor-phase process. The solid encapsulate 50 may be a polymer, or an oxide layer. The solid encapsulate 50 is selected such that it does not dissolve the perovskite nanocrystals 40 nor the host matrix while maintaining impermeability to oxygen and moisture to keep the materials stable. Example solid encapsulates include poly (methyl methacrylate), parylene, polystyrene and spin-on glass.

Further, while FIGS. 1A-1D show a thermal probe, the method is not limited to thermal scanning probe lithography and may be used with other techniques of local heating, such as direct laser heating, or dielectric or plasmonic nanostructures with diffraction limited or sub-diffraction optical mode under laser illumination leading to small thermal volumes to promote localized on-site growth and even self-aligned with optical/plasmonic structures for engineering and enhancing emission characteristics.

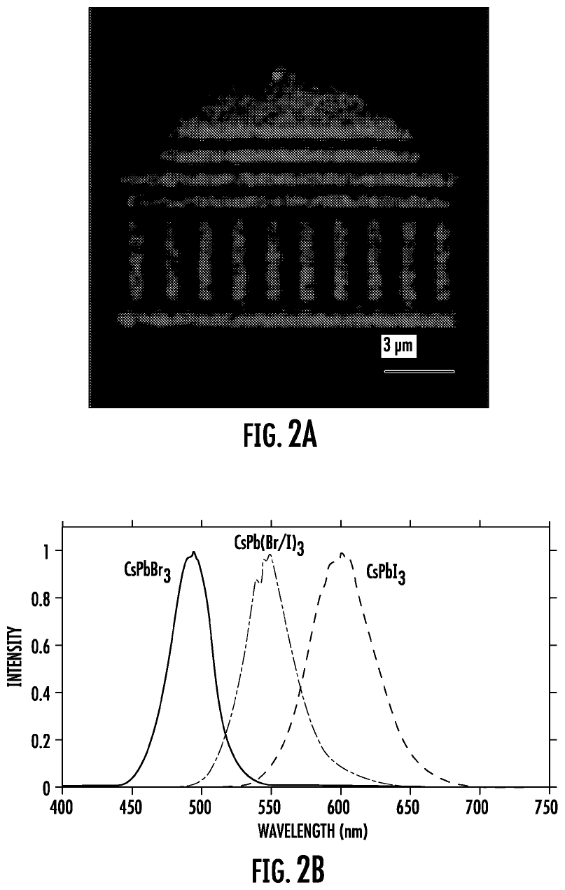

FIG. 2A illustrates patterned perovskite nanocrystals grown through the thermal scanning probe lithography shown in FIGS. 1A-1D. The nanocrystals shown are CsPbIs, however the technique may be extended to other perovskite types and compositions (such as CsPbBr₃ or CsPb (Br/I)₃). FIG. 2A shows a photoluminescence (PL) map of grown CsPbI₃ nanocrystals in a dome pattern. Specifically, in this example, the dome pattern is composed of CsPbI₃ quantum dots embedded in a host matrix of poly (methyl methacrylate).

FIG. 2B shows the PL spectra of example-grown nanocrystals with different perovskite compositions showing the tunability of the emission wavelength. Specifically, in addition to CsPbI₃, CsPbBr3 and CsPb (Br/I)₃ are shown.

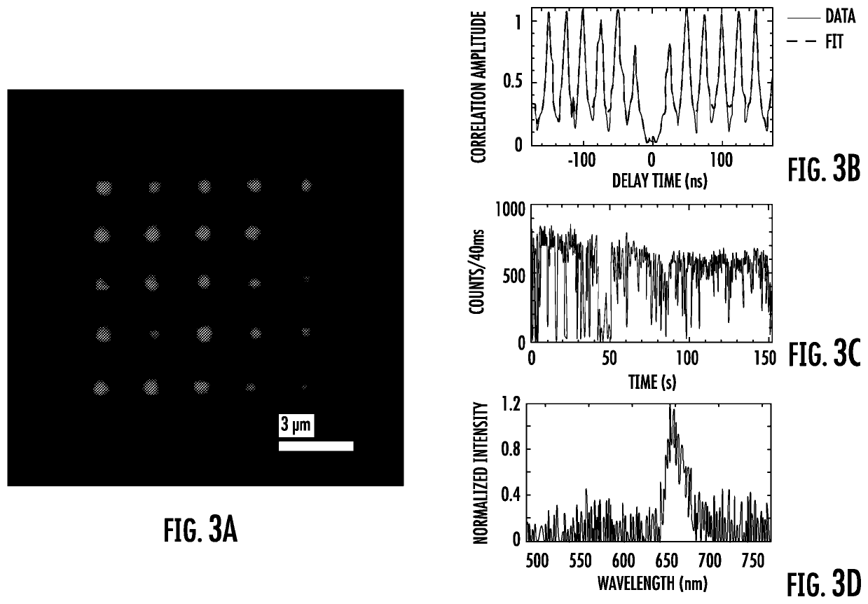

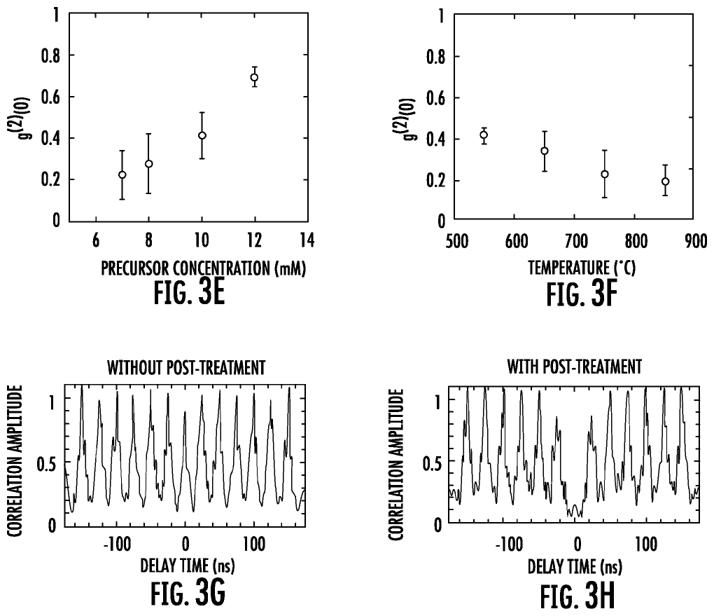

FIGS. 3A-3H demonstrate that the deterministic patterning allowed by this method may be further extended to single-site patterning, where a thermal volume generated by the heated tip confines the growth of perovskite nanocrystals to their immediate vicinity. Controlled growth of single-emitter (for example, on-site growth of individual quantum dots) may be facilitated by controlling the precursor concentration, surface passivation ligand type and concentration, growth temperature, film thickness, and post-growth treatments. FIG. 3A shows an example PL map of a patterned array of localized nanocrystals.

FIGS. 3B-3D show a room temperature intensity correlation [g⁽²⁾(τ) ], time trace, and photoluminescent spectrum, respectively, of a nanocrystal growth site exhibiting strong antibunching [g⁽²⁾(0)=0.02] which is indicative of a single emitter, while also displaying an on-fraction of 90%. On-fraction refers to the fraction of time that a given emitter is in the optically bright state when excited with light. It is desirable to have this number close to unity. Single perovskite emitters are indicated by low g⁽²⁾(0) values, such that g⁽²⁾(0)<0.5. This illustrates that this method deterministically fabricated single photon sources that are very desirable for rapidly growing applications in quantum information technologies.

FIGS. 3E-3F shows that the number of emitting nanocrystals (which may be deduced based on the g⁽²⁾(0) value) may be tuned by changing the precursor concentration and growth temperature, respectively. In this disclosure, “the number of emitting nanocrystals” refers to the number of emitting sources at each site. As shown in FIG. 3F, an increase in growth temperature allows for the direct formation of single-emitting nanocrystals due to fewer formation sites within the host matrix. Likewise, as shown in FIG. 3E, a decrease in the precursor concentration in the perovskite forming precursor solution increases the likelihood of growing single-emitters as the amount of available precursor is limited.

In addition, the controlled growth of an individual emitter can be facilitated by a thinner deposited perovskite forming precursor film. A thinner deposited perovskite forming precursor film reduces the number of formation sites and therefore allows fewer nanocrystals to be grown. Further, through post-treatment using the post-growth solution with surface passivating ligands, the number of emitters in each site may be limited to one through selective dissolution of smaller nanocrystals and further improve the emitter quality through surface healing. This is shown in FIGS. 3G-3H. In FIG. 3G, which is measured before post-treatment, the g⁽²⁾(0) is 0.80, implying multiple emitters exist in the same growth site. However, after post-treatment, as shown in FIG. 3H, the g⁽²⁾(0) is reduced to 0.13, which is indicative of a single emitter. This method also allows control over nanocrystal size and composition. Through the choice of the host matrix, post-treatment precursors and ligands that are integrated with the host matrix for surface passivation and antioxidation, the nanocrystals may acquire improved optical stability and suppressed optical blinking. This may be due to reduced exposure to oxygen and moisture, and reduction in surface charges and surface defects.

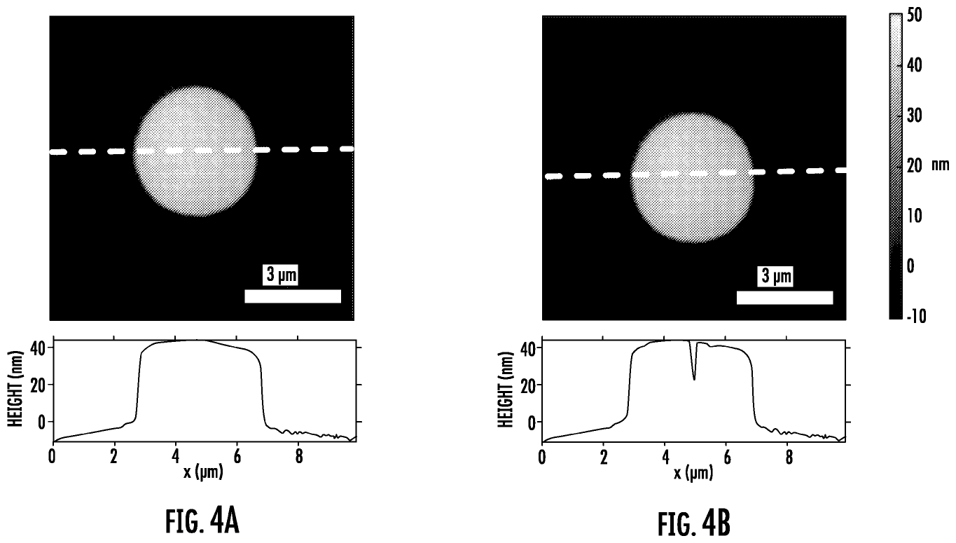

The precise on-site synthesis of perovskite emitters relative to existing structures or devices on the substrate is essential for electrical, optical, and optoelectronics system integration. This process allows the integration of nanocrystals with other materials, structures, and devices with this method through the aligned growth of nanocrystals on optical, photonic, and/or electrical structures. FIGS. 4A-4B demonstrate the precise coupling of grown emitters relative to an existing optical structure. FIG. 4A shows an atomic force microscope (AFM) scan of a circular feature resembling an example optical cavity structure before introducing patterned emitters in the center of the structure.

FIG. 4B shows the atomic force microscope (AFM) scan of a circular feature after introducing patterned emitters in the center of the structure. The narrow downward peak located at about 5 μm is the position of the nanocrystal. Note that the nanocrystal was deposited nearly in the center of the circular feature.

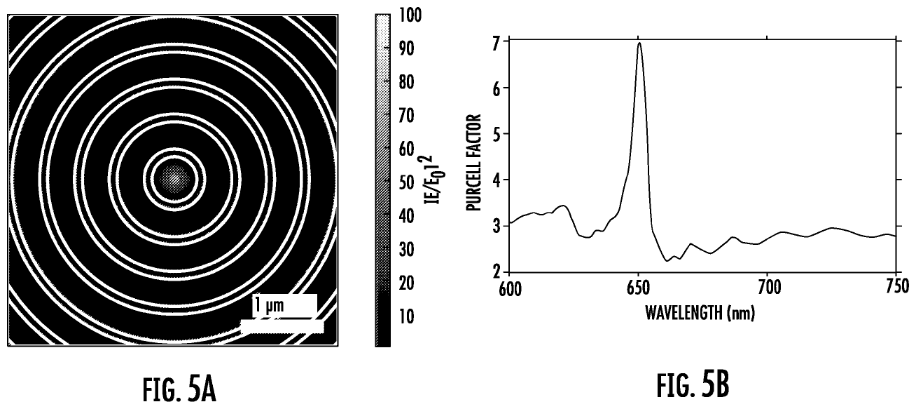

FIGS. 5A-5B show simulations of the electric field intensity distribution of a patterned emitter within a circular Bragg grating and its Purcell enhancement spectrum, respectively. The optical cavity enhances the local density of states of the emitter, and thereby can amplify its spontaneous emission rate and shorten its radiative lifetime. By designing the cavity to align its resonance energy with the emission energy of the grown nanocrystal, the Purcell factor of the cavity at the nanocrystal emission energy may allow the lifetime of the emitter to reach its coherence time at cryogenic temperatures, resulting in a deterministic, on-demand, and coherent single-photon source serving as a core component for emerging quantum information technologies

The present system has many advantages. This method is versatile and allows integration into diverse structures, which are not limited to the photonic structure described herein. Other optical cavities with diverse designs, as well as other types of structures including plasmonic cavities, or electrical structures, such as contact electrodes, are also feasible. This method is compatible with other fabrication techniques such that the t emitters can be integrated with prefabricated structures, devices, and CMOS chips readily and without damage. Additional fabrication steps may also be conducted following nanocrystal growth.

Furthermore, with easily tunable bandgaps and low formation energies, perovskite nanocrystals show great applicability in a myriad of areas, ranging from optoelectronics (e.g., solar cells, light-emitting diodes, lasers, and photodetectors), to electronics (e.g. memristors and neuromorphic devices) to quantum information technologies (e.g., quantum computing, communication, cryptography, and sensing). This method makes it possible to achieve the deterministic on-site formation of perovskite nanocrystals down to an individual quantum emitter, which is not feasible conventionally. This opens opportunities for integration of halide perovskites to on-chip device applications including the fabrication of lasers, nanoscale light-emitting diodes, and memristors, to name a few examples. Uniquely and significantly, this method also allows control down to individual quantum emitters, enabling the deterministic formation of quantum light sources for applications in quantum technologies, such as quantum computers and sensors. On-demand emitters have been reliably integrated with other optical and electrical structures to demonstrate deterministic single-photon sources. Such deterministic quantum light sources have been highly desired as they are a core component of many photonic quantum technologies. Moreover, this method may be expanded to various methods of local heating and maintains control over composition, size, and a surface passivation, further increasing the relevance of this approach. It should be noted that this method is not limited to halide perovskites and can also allow local control and on-site growth of other materials whose formation is compatible with this method.

Further, as the dimension of a semiconductor nanocrystal reduces to the nanometer scale, its spatial confinement allows individual excited exciton in the semiconductor nanocrystal to emit non-classical single-photons. Such nanocrystals may be used as single-photon sources to generate coherent and indistinguishable single-photon per excitation pulse. Single-photon sources are one of the fundamental quantum hardware elements for many proposed schemes such as quantum computing, quantum key distribution for secure information transmission, quantum random number generation, and quantum optical metrology and imaging. As such, this technique enables deterministic and scalable fabrication of quantum light sources on-chip that may be applied towards quantum technologies.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A method of forming nanocrystals on a substrate, comprising:
preparing a perovskite forming precursor solution;
depositing the perovskite forming precursor solution on a substrate to produce a layer comprising perovskite precursors, referred to as a deposited perovskite forming precursor film; and
locally heating a region of the deposited perovskite forming precursor film to transform the perovskite precursors into perovskite nanocrystals and
deterministically form an arbitrary pattern comprising clusters of the perovskite nanocrystals.

2. The method of claim 1, wherein the perovskite forming precursor solution comprises a mixture of a solvent and the perovskite precursors.

3. The method of the claim 2, wherein the perovskite precursors are metal halide perovskite precursors.

4. The method of claim 2, wherein the perovskite forming precursor solution comprises surface passivation ligands.

5. The method of claim 2, wherein the perovskite forming precursor solution comprises a host matrix.

6. The method of claim 4, wherein the surface passivation ligands are oleylamine, oleic acid, octylamine bromide or a mixture thereof.

7. The method of claim 5, wherein the host matrix comprises a polymer, poly(methyl methacrylate), polystyrene or spin-on glass.

8. (canceled)

9. The method of claim 1, wherein the perovskite forming precursor solution is deposited using spin-coating or blade-coating.

10. The method of claim 1, wherein the local heating is performed using a thermal scanning probe.

11. The method of claim 1, wherein the local heating is performed using a laser.

12. The method of claim 11, wherein the laser is used in presence of an optical/plasmonic feature to allow light localization resulting in localized heating.

13. The method of claim 1, further comprising exposing the perovskite nanocrystals to a post-growth solution comprising surface passivation ligands.

14. The method of claim 13, wherein the post-growth solution comprises a solvent.

15. The method of claim 14, wherein the post-growth solution comprises one or more perovskite precursors.

16. The method of claim 1, further comprising depositing an inert gas and/or a solid encapsulate to encapsulate the perovskite nanocrystals, wherein the solid encapsulate is impermeable to oxygen and moisture.

17. The method of claim 16, wherein the solid encapsulate comprises poly (methyl methacrylate), parylene, polystyrene or spin-on glass.

18. The method of claim 1, wherein nanocrystals with a single photon emitter are generated.

19. The method of claim 18, wherein growth temperature is varied to allow direct formation of single photon emitting nanocrystals.

20. The method of claim 18, wherein a thickness of the deposited perovskite forming precursor film is varied to allow direct formation of single photon emitting nanocrystals.

21. The method of claim 18, wherein a concentration of the perovskite precursors in the perovskite forming precursor solution is varied to allow direct formation of single photon emitting nanocrystals.

22. (canceled)

23. (canceled)

24. (canceled)

25. (canceled)
